(19) United States
(12) Patent Application Publication
(10) Pub. No.: US 2024/0421097 A1
(43) Pub. Date: Dec. 19, 2024

(54) SEMICONDUCTOR MODULE

(71) Applicant: FUJI ELECTRIC CO., LTD., Kawasaki-shi (JP)

(72) Inventor: Kenshirou ICHIYASU, Matsumoto-city (JP)

(73) Assignee: FUJI ELECTRIC CO., LTD., Kawasaki-shi (JP)

(21) Appl. No.: 18/646,110

(22) Filed: Apr. 25, 2024

(30) Foreign Application Priority Data
Jun. 15, 2023 (JP) 2023-098498

(51) Int. Cl. H01L 23/538; H01L 23/00; H01L 23/498; H01L 25/07

(52) U.S. Cl. CPC H01L 23/5386; H01L 23/49866; H01L 25/072; H01L 24/48; H01L 2224/48225

(57) ABSTRACT

A semiconductor module includes: a first semiconductor switching element including a first input electrode and a first output electrode; a second semiconductor switching element including a second input electrode and a second output electrode; an input part that receives an input of current; a first connection part that electrically connects the first input electrode and the input part; a second connection part that electrically connects the second input electrode and the input part; and an output part electrically connected to the first output electrode and the second output electrode. Each of the first connection part and the second connection part includes, as a current path, a variable resistive member comprising material with a positive temperature resistance coefficient higher than a temperature resistance coefficient of material of the input part.

### CROSS REFERENCE TO RELATED APPLICATION

This application is based on, and claims priority from, Japanese Patent Application No. 2023-098498, filed Jun. 15, 2023, the entire content of which is incorporated herein by reference.

### BACKGROUND OF THE INVENTION

### Field of the Invention

The present disclosure relates to a semiconductor module.

### Description of Related Art

In a semiconductor module typified by a power semiconductor module, a plurality of switching elements such as IGBT (Insulated Gate Bipolar Transistor) elements may be electrically connected in parallel to each other as disclosed in, for example, Japanese Patent Application Laid-Open Publication No. 2000-311983, Japanese Patent Application Laid-Open Publication No. 2001-94035, and Japanese Patent Application Laid-Open Publication No. 2022-2380.

In the semiconductor module described in Japanese Patent Application Laid-Open Publication No. 2000-311983, on each principal current paths of a plurality of power semiconductor elements connected in parallel to each other, a control element having a resistance value that increases due to a phase transition at a certain temperature is connected in series to each of the power semiconductor elements. This control element acts to reduce a current imbalance between parallel circuits. This prevents a current flow from concentrating only on a particular power semiconductor element, and thus prevents the particular power semiconductor element from being damaged by an excessive increase in temperature. The control element is joined onto an emitter electrode that is an output-side electrode of the power semiconductor element.

In the semiconductor module described in Japanese Patent Application Laid-Open Publication No. 2000-311983, it is necessary to join the control element to the emitter electrode of the power semiconductor element. This greatly complicates the manufacturing process of the semiconductor module, and thus results in a problem that it is difficult to reduce costs associated with manufacturing of the semiconductor module.

### SUMMARY OF THE INVENTION

In view of the above circumstances, an object of one aspect of the present disclosure is to improve reliability of a semiconductor module in which a plurality of semiconductor switching elements are electrically connected in parallel to each other, while reducing costs associated with manufacturing of the semiconductor module.

In order to solve the above problem, a semiconductor module according to a preferred aspect of the present disclosure includes: a first semiconductor switching element including a first input electrode and a first output electrode; a second semiconductor switching element including a second input electrode and a second output electrode; an input part configured to receive an input of current; a first connection part configured to electrically connect the first input electrode and the input part; a second connection part configured to electrically connect the second input electrode and the input part; and an output part electrically connected to the first output electrode and the second output electrode, in which each of the first connection part and the second connection part includes, as a current path, a variable resistive member comprising material with a positive temperature resistance coefficient higher than a temperature resistance coefficient of material of the input part.

### BRIEF DESCRIPTION OF THE DRAWINGS

FIG. 1 is a plan view of a semiconductor module according to a First Embodiment;

FIG. 2 is a cross-sectional view taken along a line A-A in FIG. 1;

FIG. 3 is a cross-sectional view taken along a line B-B in FIG. 1;

FIG. 4 is a circuit diagram of the semiconductor module illustrated in FIG. 1;

FIG. 5 is an explanatory plan view of a first connection part and a second connection part in the First Embodiment;

FIG. 6 is a plan view of a semiconductor module according to a Second Embodiment;

FIG. 7 is a plan view of a semiconductor module according to a Third Embodiment;

FIG. 8 is a plan view of a semiconductor module according to a Fourth Embodiment;

FIG. 9 is a cross-sectional view of a semiconductor module according to a Fifth Embodiment;

FIG. 10 is a plan view of a semiconductor module according to a Sixth Embodiment; and

FIG. 11 is a cross-sectional view taken along a line C-C in FIG. 10.

### DESCRIPTION OF THE EMBODIMENTS

Preferred embodiments according to the present disclosure are explained below with reference to the attached drawings. It is to be noted that the dimensions and scales of respective parts in the drawings may be different from those of actual products as appropriate and illustrative parts may be included in the drawings to facilitate understanding. The scope of the present disclosure is not limited to these embodiments unless there are descriptions particularly limiting the present disclosure in the following explanations.

### 1. First Embodiment

### 1-1. Overall Configuration of Semiconductor Module

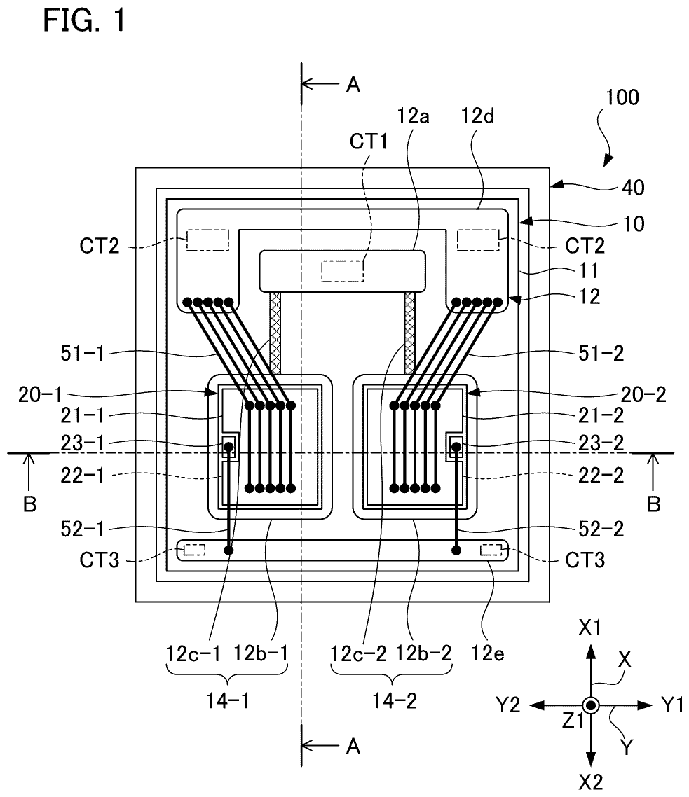

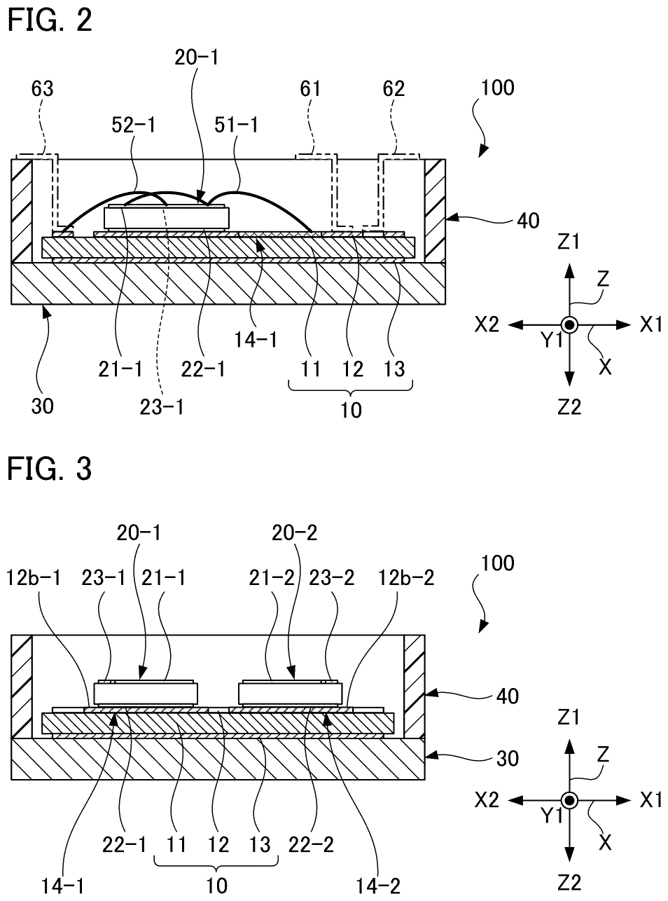

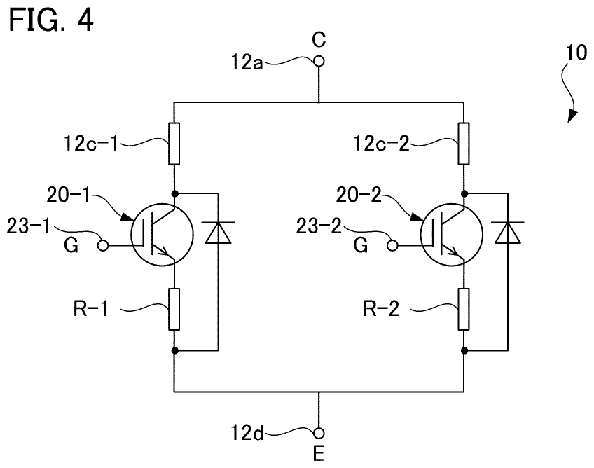

FIG. 1 is a plan view of a semiconductor module 100 according to a First Embodiment. FIG. 2 is a cross-sectional view taken along a line A-A in FIG. 1. FIG. 3 is a cross-sectional view taken along a line B-B in FIG. 1. FIG. 4 is a circuit diagram of the semiconductor module 100 illustrated in FIG. 1. In FIG. 1, for better visibility, an external input terminal 61, an external output terminal 62, and a control terminal 63 are omitted, which will be described later. In FIG. 3, for better visibility, wires 51-1, 51-2, 52-1, and 52-2 as well as the external input terminal 61, the external output terminal 62, and the control terminal 63 are omitted. The wires 51-1, 51-2, 52-1, and 52-2 will be described later.

The semiconductor module 100 is a power semiconductor module to be used in a power conversion device such as an inverter circuit. As illustrated in FIGS. 1 to 3, the semiconductor module 100 includes a substrate 10, a first semiconductor switching element 20-1, a second semiconductor switching element 20-2, a base 30, a casing 40, the wires 51-1, 51-2, 52-1, and 52-2, the external input terminal 61, the external output terminal 62, and the control terminal 63.

First, the outline of each part of the semiconductor module 100 is described below sequentially with reference to FIGS. 1 to 3. In the following descriptions, for convenience of description, each part of the semiconductor module 100 is described using an X-axis, a Y-axis, and a Z-axis perpendicular to each other as appropriate. The Z-axis is parallel to a thickness direction or a height direction of the semiconductor module 100. In the following descriptions, one direction along the X-axis is an X1 direction, while another direction opposite to the X1 direction is an X2 direction. One direction along the Y-axis is a Y1 direction, while another direction opposite to the Y1 direction is a Y2 direction. One direction along the Z-axis is a Z1 direction, while another direction opposite to the Z1 direction is a Z2 direction. The relationships between these directions and the vertical direction are not particularly limited, and there may be any relationship thereamong. Viewing in a direction along the Z-axis may be hereinafter referred to as “plan view”.

In the following descriptions, the first semiconductor switching element 20-1 and the second semiconductor switching element 20-2 may be collectively referred to as “semiconductor switching element 20” without distinguishing therebetween.

The substrate 10 is accommodated in the casing 40 and is configured to support the first semiconductor switching element 20-1 and the second semiconductor switching element 20-2. Examples of the substrate 10 to be used include a DCB (Direct Copper Bonding) substrate, an AMB (Active Metal Brazing) substrate, and an IMS (Insulated Metal Substrate). The shape of the substrate 10 in plan view is not limited to the example illustrated in FIG. 1, and the substrate 10 may have any shape in plan view.

As illustrated in FIGS. 2 and 3, the substrate 10 includes an insulating substrate 11, a conductor pattern group 12, and a metal layer 13.

The insulating substrate 11 is a plate-like member with insulation properties, and comprises ceramics such as aluminum nitride, aluminum oxide, or silicon nitride. The conductor pattern group 12 is provided on one surface of the insulating substrate 11, while the metal layer 13 is provided on the other surface.

The conductor pattern group 12 is made up of a plurality of conductor patterns to be joined to a surface of the insulating substrate 11 which faces in the Z1 direction. As illustrated in FIG. 1, the conductor pattern group 12 includes an input part 12a, a first pad 12b-1, a second pad 12b-2, a first wiring 12c-1, a second wiring 12c-2, an output part 12d, and a control pattern 12e.

The input part 12a is a conductor pattern configured to receive an input of current from the external input terminal 61. The external input terminal 61 is joined to the input part 12a in a region CT1 illustrated by the dash-double-dot line in FIG. 1 through a conductive joining material such as solder. In the example illustrated in FIG. 1, the input part 12a has a shape extending in a direction along the Y-axis. The shapes and positions of the input part 12a and the region CT1 are not limited to the example illustrated in FIG. 1, and the input part 12a and the region CT1 may have any shape and be located at any position. The input part 12a may be divided into a portion for supplying a current to the first semiconductor switching element 20-1 and a portion for supplying a current to the second semiconductor switching element 20-2. In this case, the external input terminal 61 to which these portions are connected in common corresponds to the “input part”.

The first pad 12b-1 is a conductor pattern joined to the underside of the first semiconductor switching element 20-1. Accordingly, the first pad 12b-1 is electrically connected to a first input electrode 22-1. The second pad 12b-2 is a conductor pattern joined to the underside of the second semiconductor switching element 20-2. Accordingly, the second pad 12b-2 is electrically connected to a second input electrode 22-2. In the example illustrated in FIG. 1, the first pad 12b-1 and the second pad 12b-2 are arranged side by side in a direction along the Y-axis at a position in the X2 direction relative to the input part 12a. The shapes and positions of the first pad 12b-1 and the second pad 12b-2 are not limited to the examples illustrated in FIG. 1, and the first pad 12b-1 and the second pad 12b-2 may have any shape and be located at any position.

The first wiring 12c-1 is a conductor pattern configured to serve as a current path electrically connecting the input part 12a and the first pad 12b-1. That is, the first wiring 12c-1 is a conductor pattern constituting a wiring having one end connected to the input part 12a and the other end connected to the first pad 12b-1. The second wiring 12c-2 is a conductor pattern configured to serve as a current path electrically connecting the input part 12a and the second pad 12b-2. That is, the second wiring 12c-2 is a conductor pattern constituting a wiring having one end connected to the input part 12a and the other end connected to the second pad 12b-2. In the example illustrated in FIG. 1, the first wiring 12c-1 is positioned between the input part 12a and the first pad 12b-1, and the second wiring 12c-2 is positioned between the input part 12a and the second pad 12b-2. Each of the first wiring 12c-1 and the second wiring 12c-2 has a shape extending linearly in a direction along the X-axis. The shapes and positions of the first wiring 12c-1 and the second wiring 12c-2 are not limited to the example illustrated in FIG. 1, and the first wiring 12c-1 and the second wiring 12c-2 may have any shape and be located at any position. Examples of these wirings in another mode are described later in a Second Embodiment to a Sixth Embodiment. However, from the viewpoint of aligning the resistance-value change characteristics of the first wiring 12c-1 and the second wiring 12c-2 (described later), it is preferable that the first wiring 12c-1 and the second wiring 12c-2 be configured symmetrical in a direction along the Y-axis.

The output part 12d is a conductor pattern configured to output a current to the external output terminal 62. The external output terminal 62 is joined to the output part 12d in regions CT2 illustrated by the dash-double-dot line in FIG. 1 through a conductive joining material such as solder. The output part 12d is spaced apart from the input part 12a, the first pad 12b-1, the second pad 12b-2, the first wiring 12c-1, the second wiring 12c-2, and the control pattern 12e. In the example illustrated in FIG. 1, the output part 12d has a shape extending in a direction along the Y-axis at a position in the X1 direction relative to the input part 12a. The shapes and positions of the output part 12d and the regions CT2 are not limited to the examples illustrated in FIG. 1, and the output part 12d and the regions CT2 may have any shape and be located at any position. The output part 12d may be divided into a portion for receiving an output current from the first semiconductor switching element 20-1 and a portion for receiving an output current from the second semiconductor switching element 20-2. In this case, the external output terminal 62 to which these portions are connected in common corresponds to the “output part”.

The control pattern 12e is a conductor pattern configured to receive a control signal from the control terminal 63. The control terminal 63 is joined to the control pattern 12e in regions CT3 illustrated by the dash-double-dot line in FIG. 1 through a conductive joining material such as solder. The control pattern 12e is spaced apart from the input part 12a, the first pad 12b-1, the second pad 12b-2, the first wiring 12c-1, the second wiring 12c-2, and the output part 12d. In the example illustrated in FIG. 1, the control pattern 12e has a shape extending in a direction along the Y-axis at a position in the X2 direction relative to the first pad 12b-1 and the second pad 12b-2. The shapes and positions of the control pattern 12e and the regions CT3 are not limited to the examples illustrated in FIG. 1, and the control pattern 12e and the regions CT3 may have any shape and be located at any position.

All the above constituent elements of the conductor pattern group 12, except the first wiring 12c-1 and the second wiring 12c-2, comprise metal material with high thermal conductivity, such as copper or aluminum. Surfaces of the input part 12a, the first pad 12b-1, the second pad 12b-2, the output part 12d, and the control pattern 12e may be subjected to plating treatment with nickel or other plating material.

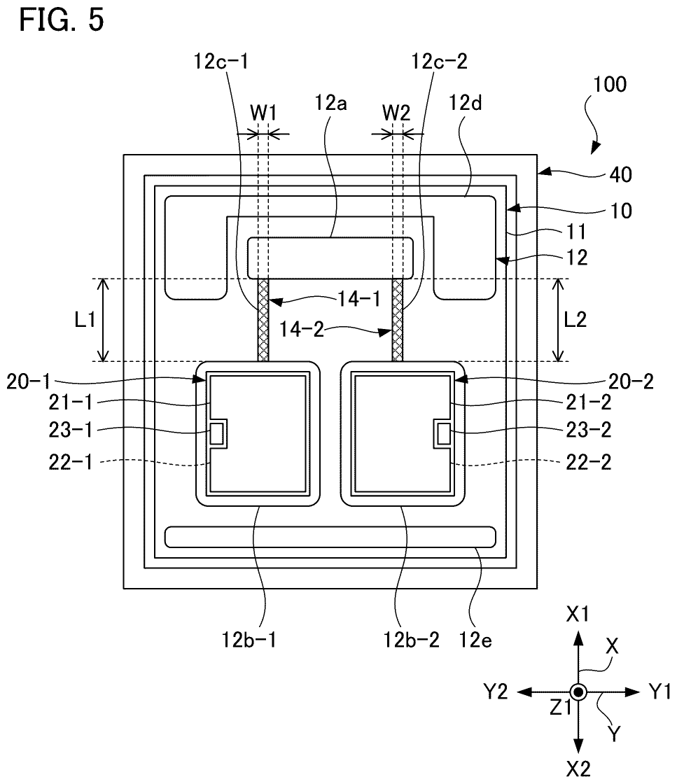

In contrast, each of the first wiring 12c-1 and the second wiring 12c-2 is a member comprising material with a positive temperature resistance coefficient higher than the temperature resistance coefficient of the material of the input part 12a and other elements described above. This member is described later in detail with reference to FIG. 5. In the following descriptions, such member may be referred to as “variable resistive member or resistance changing member”.

The metal layer 13 is a metal plate joined to a surface of the insulating substrate 11 which faces in the Z2 direction. The metal layer 13 comprises metal such as copper or aluminum. The metal layer 13 is configured to transfer heat from the first semiconductor switching element 20-1 and the second semiconductor switching element 20-2 to the base 30, and is joined to the base 30 through a conductive joining material such as solder.

Each of the first semiconductor switching element 20-1 and the second semiconductor switching element 20-2 is a switching element such as an IGBT (Insulated Gate Bipolar Transistor) or a power MOSFET (metal-oxide-semiconductor field-effect transistor).

As illustrated in FIG. 3, the first semiconductor switching element 20-1 includes a first output electrode 21-1, the first input electrode 22-1, and a control electrode 23-1. The first input electrode 22-1 is a drain electrode or a collector electrode provided on the underside of the first semiconductor switching element 20-1. The first output electrode 21-1 is a source electrode or an emitter electrode provided on the topside of the first semiconductor switching element 20-1. The control electrode 23-1 is a gate electrode provided on the topside of the first semiconductor switching element 20-1.

In substantially the same manner as the first semiconductor switching element 20-1, the second semiconductor switching element 20-2 includes a second output electrode 21-2, the second input electrode 22-2, and a control electrode 23-2. The second input electrode 22-2 is a drain electrode or a collector electrode provided on the underside of the second semiconductor switching element 20-2. The second output electrode 21-2 is a source electrode or an emitter electrode provided on the topside of the second semiconductor switching element 20-2. The control electrode 23-2 is a gate electrode provided on the topside of the second semiconductor switching element 20-2.

In the present embodiment, each of the first semiconductor switching element 20-1 and the second semiconductor switching element 20-2 is an RC (Reverse-Conducting)-IGBT or other element having both the functions of an IGBT and an FWD (Freewheeling Diode). Each of the first semiconductor switching element 20-1 and the second semiconductor switching element 20-2 thus includes a diode such as the FWD in addition to the switching element itself. Consequently, each of the first input electrode 22-1 and the second input electrode 22-2 serves not only as a drain electrode or a collector electrode, but also as a cathode electrode. Each of the first output electrode 21-1 and the second output electrode 21-2 serves not only as a source electrode or an emitter electrode, but also as an anode electrode. Each of the first semiconductor switching element 20-1 and the second semiconductor switching element 20-2 may be made up of only the IGBT. In this case, the FWD may be mounted on the substrate 10 separately from the first semiconductor switching element 20-1 and the second semiconductor switching element 20-2. The FWD may be provided as needed or may be omitted. That is, it is sufficient that each of the first semiconductor switching element 20-1 and the second semiconductor switching element 20-2 includes a switching element such as the IGBT.

As illustrated in FIG. 3, the first input electrode 22-1 is joined to a surface of the first pad 12b-1 of the substrate 10 through a conductive joining material such as solder. The surface of the first pad 12b-1 to which the first input electrode 22-1 is joined faces in the Z1 direction.

With this configuration, the first input electrode 22-1 is electrically connected to the input part 12a through the first pad 12b-1 and the first wiring 12c-1. The first pad 12b-1 and the first wiring 12c-1 constitute a first connection part 14-1, and electrically connect the input part 12a and the first input electrode 22-1.

In substantially the same manner as the first input electrode 22-1, the second input electrode 22-2 is joined to a surface of the second pad 12b-2 of the substrate 10 described above through a conductive joining material such as solder. The surface of the second pad 12b-2 to which the second input electrode 22-2 is joined faces in the Z1 direction. With this configuration, the second input electrode 22-2 is electrically connected to the input part 12a through the second pad 12b-2 and the second wiring 12c-2. The second pad 12b-2 and the second wiring 12c-2 constitute a second connection part 14-2, and electrically connect the input part 12a and the second input electrode 22-2.

In the manner as described above, the first input electrode 22-1 and the second input electrode 22-2 are electrically connected in parallel to the input part 12a.

In contrast, the first output electrode 21-1 is electrically connected to the output part 12d of the substrate 10 described above through the wires 51-1. The wires 51-1 are a group of wires having one end joined to the first output electrode 21-1 and the other end joined to the output part 12d. In substantially the same manner as the first output electrode 21-1, the second output electrode 21-2 is electrically connected to the output part 12d through the wires 51-2. The wires 51-2 are a group of wires with one end of the respective wire joined to the second output electrode 21-2 and the other end joined to the output part 12d.

In the manner as described above, the first output electrode 21-1 and the second output electrode 21-2 are electrically connected in parallel to the output part 12d.

The control electrode 23-1 is electrically connected to the control pattern 12e on the substrate 10 described above through the wire 52-1. The wire 52-1 is a bonding wire having one end joined to the control electrode 23-1 and the other end joined to the control pattern 12e. In substantially the same manner as the control electrode 23-1, the control electrode 23-2 is electrically connected to the control pattern 12e through the wire 52-2. The wire 52-2 is a bonding wire having one end joined to the control electrode 23-2 and the other end joined to the control pattern 12e.

The base 30 is a plate-like member for heat dissipation, and constitutes a bottom plate of the semiconductor module 100. The substrate 10 is joined to a surface of the base 30 which faces in the Z1 direction. A heat dissipation member such as a heat dissipation fin (not illustrated) may be joined to a surface of the base 30, the surface facing in the Z2 direction. For example, the base 30 is a metal plate comprising copper, copper alloy, aluminum, or aluminum alloy. The base 30 is thermally conductive and dissipates heat from the first semiconductor switching element 20-1 and the second semiconductor switching element 20-2. The base 30 is electrically conductive and may be electrically connected to a reference potential such as a ground potential. The shape of the base 30 in plan view is not limited to the example illustrated in FIG. 1, and the base 30 may have any shape in plan view.

The casing 40 is a frame-like member in which the first semiconductor switching element 20-1 and the second semiconductor switching element 20-2 are accommodated. In the examples illustrated in FIGS. 2 and 3, the casing 40 is joined to a surface of the base 30, the surface facing in the Z1 direction with an adhesive or the like. The casing 40 is substantially an insulator. The casing 40 comprises resin material such as PPS (polyphenylene sulfide) or PBT (polybutylene terephthalate) and formed by injection molding or other molding methods. The resin material may contain inorganic fiber such as glass fiber, or may contain inorganic filler such as alumina or silica to improve mechanical strength or thermal conductivity of the casing 40. The shape of the casing 40 is not limited to the example illustrated in FIGS. 1 to 3, and the casing 40 may have any shape.

The casing 40 is filled with a sealing resin (not illustrated). The sealing resin is a potting material to cover the first semiconductor switching element 20-1 and the second semiconductor switching element 20-2. The sealing resin comprises a thermosetting resin such as an epoxy resin or a silicone resin. The sealing resin may contain inorganic filler such as silica or alumina intended to increase the thermal conductivity. A sealing resin in gel form may also be used.

Each of the external input terminal 61 and the external output terminal 62 is connected to a busbar (not illustrated). The external input terminal 61 is a terminal through which the principal current is input. The external output terminal 62 is a terminal through which the principal current is output. Each of the external input terminal 61 and the external output terminal 62 comprises metal such as copper, copper alloy, aluminum, aluminum alloy, or iron alloy, and is constituted of a bent metal plate.

The control terminal 63 is a terminal through which a control signal is input, and is connected to a substrate (not illustrated). The control terminal 63 comprises metal such as copper, copper alloy, aluminum, aluminum alloy, or iron alloy, and is formed by bending a metal plate.

As illustrated in FIG. 4, in the semiconductor module 100 described above, the first semiconductor switching element 20-1 and the second semiconductor switching element 20-2 are electrically connected in parallel to each other. The first semiconductor switching element 20-1 has an internal resistance R-1. The second semiconductor switching element 20-2 has an internal resistance R-2.

In the first semiconductor switching element 20-1 and the second semiconductor switching element 20-2, there may be a difference between the internal resistance R-1 and the internal resistance R-2 due to manufacturing variations, aging degradation, or other factors. In this case, assuming that an equal current is supplied to the first semiconductor switching element 20-1 and the second semiconductor switching element 20-2, the difference in internal resistance causes the current to concentrate on one of the first semiconductor switching element 20-1 and the second semiconductor switching element 20-2. As a result, the one semiconductor switching element 20 is more likely to be degraded by an excessive increase in temperature.

In view of this, in order to reduce such degradation of the semiconductor switching element 20, each of the first wiring 12c-1 and the second wiring 12c-2 includes the variable resistive member comprising material with a positive temperature resistance coefficient higher than the temperature resistance coefficient of the material of the input part 12a as described above. With reference to FIG. 5, explanations are given below in this regard.

### 1-2. First Connection Part and Second Connection Part

FIG. 5 is an explanatory plan view of the first connection part 14-1 and the second connection part 14-2 in the First Embodiment. In FIG. 5, for better visibility, wires 51-1, 51-2, 52-1, and 52-2, which will be described later, the external input terminal 61, the external output terminal 62, and the control terminal 63 are omitted, and the variable resistive members are shaded.

As illustrated in FIG. 5, in the semiconductor module 100, both the first input electrode 22-1 and the second input electrode 22-2 are electrically connected to the input part 12a, whereas both the first output electrode 21-1 and the second output electrode 21-2 are electrically connected to the output part 12d. With this configuration, the first semiconductor switching element 20-1 and the second semiconductor switching element 20-2 are electrically connected in parallel to each other.

As described above, the first input electrode 22-1 is electrically connected to the input part 12a through the first connection part 14-1, while the second input electrode 22-2 is electrically connected to the input part 12a through the second connection part 14-2. In addition, each of the first connection part 14-1 and the second connection part 14-2 includes, as a current path, a variable resistive member that comprises material with a positive temperature resistance coefficient higher than the temperature resistance coefficient of the material of the input part 12a. In the present embodiment, each of the first wiring 12c-1 and the second wiring 12c-2 described above is the variable resistive member.

The wording “includes, as a current path,” is defined as constituting a path through which a current mainly flows. For example, in a configuration in which a low-conductivity layer plated with nickel or the like is layered on top of a high-conductivity wiring of copper or the like, a current flows mainly through the high-conductivity wiring. Accordingly, the low-conductivity layer does not meet the definition of “includes, as a current path”.

The first connection part 14-1 receives heat from the first semiconductor switching element 20-1. With this heat, a resistance value of the first connection part 14-1 increases due to the action of the variable resistive member, as the temperature of the first semiconductor switching element 20-1 increases. Accordingly, a current to be input to the first semiconductor switching element 20-1 decreases in response to the rise in temperature of the first semiconductor switching element 20-1. The second connection part 14-2 receives heat from the second semiconductor switching element 20-2. With this heat, a resistance value of the second connection part 14-2 increases due to the action of the variable resistive member, as the temperature of the second semiconductor switching element 20-2 rises. Accordingly, a current to be input to the second semiconductor switching element 20-2 decreases in response to the rise in temperature of the second semiconductor switching element 20-2.

In the configuration as described above in which the first semiconductor switching element 20-1 and the second semiconductor switching element 20-2 are electrically connected in parallel to each other, it is possible to prevent a current from being concentrated at only one of the first semiconductor switching element 20-1 and the second semiconductor switching element 20-2. As a result, it is possible to prevent a temperature increase in, and degradation of, one of the first semiconductor switching element 20-1 and the second semiconductor switching element 20-2 due to a current imbalance. Even when there are manufacturing variations between, or aging degradation occurs in, the first semiconductor switching element 20-1 and the second semiconductor switching element 20-2, it is still possible to reduce degradation in characteristics of the semiconductor module 100 by preventing a current from being concentrated at only one of the first semiconductor switching element 20-1 and the second semiconductor switching element 20-2.

The variable resistive member can be provided by being joined to the substrate 10 configured to support the first semiconductor switching element 20-1 and the second semiconductor switching element 20-2 by means of brazing or other means. Consequently, the manufacturing process of the semiconductor module 100 is more simplified, so that the cost associated with manufacturing of the semiconductor module 100 can be reduced compared to a mode in which a variable resistive member is provided on an output electrode of a semiconductor switching element as disclosed in Japanese Patent Application Laid-Open Publication No. 2000-311983.

Each of the first connection part 14-1 and the second connection part 14-2 is a conductor pattern provided on the substrate 10 as described above. It is thus possible to constitute the variable resistive member by using the conductor pattern on the substrate 10. Compared to a mode in which the variable resistive member is a bonding wire, the first connection part 14-1 and the second connection part 14-2 of desired characteristics can be obtained more easily.

As described above, the first connection part 14-1 includes the first pad 12b-1 and the first wiring 12c-1, and this first wiring 12c-1 comprises the variable resistive member. In substantially the same manner as the first connection part 14-1, the second connection part 14-2 includes the second pad 12b-2 and the second wiring 12c-2, and this second wiring 12c-2 comprises the variable resistive member. As described above, each of the first wiring 12c-1 and the second wiring 12c-2 includes the variable resistive member, so that the variable resistive member of desired characteristics can be easily obtained by appropriately changing the length, shape, or other factor of the first wiring 12c-1 and the second wiring 12c-2.

It is sufficient for the material of the variable resistive member to have a positive temperature resistance coefficient higher than the temperature resistance coefficient of the material of the input part 12a. The positive temperature resistance coefficient is preferably equal to or greater than 0.005/° C. and equal to or less than 0.007/° C., and more preferably equal to or greater than 0.006/° C. and equal to or less than 0.007/° C. In this case, it is possible to optimally prevent a temperature increase in, and degradation of, one of the first semiconductor switching element 20-1 and the second semiconductor switching element 20-2 due to a current imbalance.

For example, it is preferable that the variable resistive member constituting each of the first wiring 12c-1 and the second wiring 12c-2 comprise nickel or nickel alloy. In this case, it is possible to achieve a sufficiently significant change in the resistance value of the variable resistive member in response to a temperature change. As a result, it is possible to optimally prevent a temperature increase in, and degradation of, one of the first semiconductor switching element 20-1 and the second semiconductor switching element 20-2 due to a current imbalance.

The constituent material of each of the first wiring 12c-1 and the second wiring 12c-2 is not limited to metal such as nickel or nickel alloy, and it may be a material that has a resistance value that increases due to a phase transition at a predetermined temperature or higher, such as a first sheet member 12i-1 and a second sheet member 12i-2 described later in the Sixth Embodiment.

Where a cross-sectional area of the variable resistive member constituting each of the first wiring 12c-1 and the second wiring 12c-2 is represented as S [mm²], and where a length of the variable resistive member is represented as L [mm], it is preferable to satisfy the inequality “10≤L/S≤25,” and it is more preferable to satisfy inequality “15≤L/S≤20”. With this these inequalities, an optimal current balance between the first semiconductor switching element 20-1 and the second semiconductor switching element 20-2 can be maintained. In particular, when the variable resistive member comprises nickel or nickel alloy, it is easy to maintain the current balance between the first semiconductor switching element 20-1 and the second semiconductor switching element 20-2.

When the value of L/S is too small, a sufficiently significant change in the resistance value of the variable resistive member due to a temperature change may not be obtained depending on the type of constituent material of the variable resistive member. On the other hand, when the value of L/S is too large, the resistance of the variable resistive member is so high that a loss may excessively increase.

The cross-sectional area S is not particularly limited to a specific value and is, for example, equal to or greater than 1.0 mm² and equal to or less than 1.5 mm². Furthermore, the length L, that is, each of a length L1 of the first wiring 12c-1 and a length L2 of the second wiring 12c-2 are not particularly limited to specific values and are, for example, equal to or greater than 15 mm and equal to or less than 25 mm. A thickness of the variable resistive member constituting each of the first wiring 12c-1 and the second wiring 12c-2 is not particularly limited and is, for example, equal to or greater than 0.1 mm and equal to or less than 3 mm. Furthermore, each of a width W1 of the first wiring 12c-1 and a width W2 of the second wiring 12c-2 is not particularly limited and is, for example, equal to or greater than 2.0 mm and equal to or less than 3.0 mm.

As described above, in the First Embodiment, each of the first connection part 14-1 and the second connection part 14-2 includes, as a current path, the variable resistive member, so that it is possible to improve the reliability of the semiconductor module 100 in which a plurality of semiconductor switching elements 20 are electrically connected in parallel to each other, while reducing the cost associated with manufacturing of the semiconductor module 100.

### 2. Second Embodiment

The Second Embodiment of the present disclosure is described below. In each of the modes exemplified below, elements substantially the same in actions and functions as those described in the above embodiment are denoted by reference symbols used in the explanations of the above embodiment and respective detailed explanations thereof are omitted as appropriate.

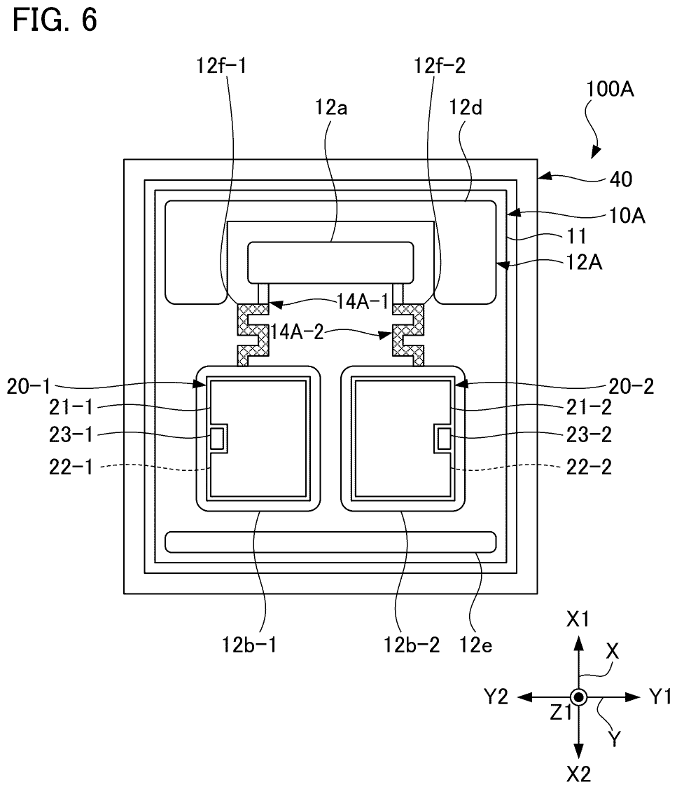

FIG. 6 is a plan view of a semiconductor module 100A according to the Second Embodiment. The semiconductor module 100A has substantially the same configuration as the semiconductor module 100 in the First Embodiment, except that the semiconductor module 100A includes a substrate 10A instead of the substrate 10 in the First Embodiment. In FIG. 6, for better visibility, wires 51-1, 51-2, 52-1, and 52-2, the external input terminal 61, the external output terminal 62, and the control terminal 63 are omitted, which have been described above, and the variable resistive members are shaded.

The substrate 10A has substantially the same configuration as the substrate 10 in the First Embodiment, except that the substrate 10A includes a conductor pattern group 12A instead of the conductor pattern group 12 in the First Embodiment. The conductor pattern group 12A has substantially the same configuration as the conductor pattern group 12 in the First Embodiment, except that the conductor pattern group 12A includes a first wiring 12f-1 and a second wiring 12f-2 instead of the first wiring 12c-1 and the second wiring 12c-2 in the First Embodiment.

The first wiring 12f-1 has substantially the same configuration as the first wiring 12c-1 in the First Embodiment, except that the first wiring 12f-1 has a different shape from that of the first wiring 12c-1 in plan view. The first pad 12b-1 and the first wiring 12f-1 constitute a first connection part 14A-1, and electrically connect the input part 12a and the first input electrode 22-1. The second wiring 12f-2 has substantially the same configuration as the second wiring 12c-2 in the First Embodiment, except that the second wiring 12f-2 has a different shape from that of the second wiring 12c-2 in plan view. The second pad 12b-2 and the second wiring 12f-2 constitute a second connection part 14A-2, and electrically connect the input part 12a and the second input electrode 22-2.

Specifically, as illustrated in FIG. 6, the first wiring 12f-1 has a shape extending in the X1 direction from the first pad 12b-1 to the input part 12a, while being alternatingly bent in the Y1 direction and the Y2 direction in a serpentine manner in plan view. In substantially the same manner as the first wiring 12f-1, the second wiring 12f-2 has a shape extending in the X1 direction from the second pad 12b-2 to the input part 12a, while being alternatingly bent in the Y1 direction and the Y2 direction in a serpentine manner in plan view.

In the example illustrated in FIG. 6, a portion of the first wiring 12f-1 and a portion of the second wiring 12f-2 in the length direction are made up of a variable resistive member. The portion of the first wiring 12f-1 and the portion of the second wiring 12f-2, which constitute the variable resistive member, have a serpentine shape in plan view. Each of the first wiring 12f-1 and the second wiring 12f-2 may be constituted of the variable resistive member in its entirety.

In the manner as described above, each of the first wiring 12f-1 and the second wiring 12f-2 includes a serpentine-shaped portion in plan view. With this configuration, the serpentine-shaped portion is used as the variable resistive member, so that it is possible to place the variable resistive member close to the first semiconductor switching element 20-1 or the second semiconductor switching element 20-2, while the variable resistive member has a desired length. As a result, it is possible to improve the responsiveness of the increase in resistance value of the first wiring 12f-1 to the temperature increase of the first semiconductor switching element 20-1, and improve the responsiveness of the increase in resistance value of the second wiring 12f-2 to the temperature increase of the second semiconductor switching element 20-2.

The shape, the number of bends, the region of the variable resistive member, and other factors of each of the first wiring 12f-1 and the second wiring 12f-2 are not limited to the example illustrated in FIG. 6. For example, each of the first wiring 12f-1 and the second wiring 12f-2 may be constituted of the variable resistive member in its entirety. Each of the first wiring 12f-1 and the second wiring 12f-2 may have such a shape as to be bent along a curve (i.e., curved) in plan view.

As described above, also in the Second Embodiment, each of the first connection part 14A-1 and the second connection part 14A-2 includes, as a current path, the variable resistive member, so that it is possible to improve the reliability of the semiconductor module 100A in which a plurality of semiconductor switching elements 20 are electrically connected in parallel to each other, while reducing the cost associated with manufacturing of the semiconductor module 100A.

### 3. Third Embodiment

The Third Embodiment of the present disclosure is described below. In respective modes exemplified below, elements substantially the same in actions and functions as those described in the above embodiments are denoted by reference symbols used in the explanations of the above embodiments and respective detailed explanations thereof are omitted as appropriate.

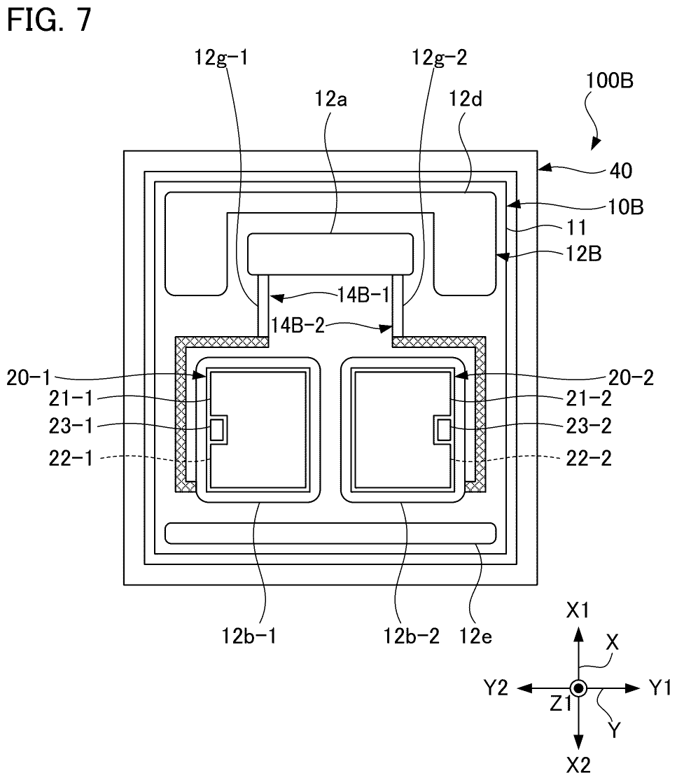

FIG. 7 is a plan view of a semiconductor module 100B according to the Third Embodiment. The semiconductor module 100B has substantially the same configuration as the semiconductor module 100 in the First Embodiment, except that the semiconductor module 100B includes a substrate 10B instead of the substrate 10 in the First Embodiment. In FIG. 7, for better visibility, the wires 51-1, 51-2, 52-1, and 52-2, the external input terminal 61, the external output terminal 62, and the control terminal 63 are omitted, which have been described above, and the variable resistive members are shaded.

The substrate 10B has substantially the same configuration as the substrate 10 in the First Embodiment, except that the substrate 10B includes a conductor pattern group 12B instead of the conductor pattern group 12 in the First Embodiment. The conductor pattern group 12B has substantially the same configuration as the conductor pattern group 12 in the First Embodiment, except that the conductor pattern group 12B includes a first wiring 12g-1 and a second wiring 12g-2 instead of the first wiring 12c-1 and the second wiring 12c-2 in the First Embodiment.

The first wiring 12g-1 has substantially the same configuration as the first wiring 12c-1 in the First Embodiment, except that the first wiring 12g-1 has a different shape from that of the first wiring 12c-1 in plan view. The first pad 12b-1 and the first wiring 12g-1 constitute a first connection part 14B-1, and electrically connect the input part 12a and the first input electrode 22-1. The second wiring 12g-2 has substantially the same configuration as the second wiring 12c-2 in the First Embodiment, except that the second wiring 12g-2 has a different shape from that of the second wiring 12c-2 in plan view. The second pad 12b-2 and the second wiring 12g-2 constitute a second connection part 14B-2, and electrically connect the input part 12a and the second input electrode 22-2.

Specifically, as illustrated in FIG. 7, each of the first pad 12b-1 and the second pad 12b-2 has a rectangular shape with first and second opposing sides extending along the X-axis and third and fourth opposing sides extending along the Y-axis in plan view. The first side is positioned in the Y2 direction relative to the second side. The third side is positioned in the X1 direction relative to the fourth side. The first wiring 12g-1 has a shape extending from the first side, which is in the Y2 direction, of the first and second sides of the first pad 12b-1 extending along the X-axis, then extending along the periphery of the first pad 12b-1, and thereafter extending toward the input part 12a in plan view. The first wiring 12g-1 extends along the first side of the first pad 12b-1, which is positioned in the Y2 direction, and the third side of the first pad 12b-1, which is positioned in the X1 direction in plan view. In substantially the same manner as the first wiring 12g-1, the second wiring 12g-2 has a shape extending from the second side in the Y1 direction of the first and second sides of the second pad 12b-2 extending along the X-axis, then extending along the periphery of the second pad 12b-2, and thereafter extending toward the input part 12a in plan view. The second wiring 12g-2 extends along the second side of the second pad 12b-2, which is positioned in the Y1 direction, and the third side of the second pad 12b-2, which is positioned in the X1 direction in plan view.

In the manner as described above, the first wiring 12g-1 includes a portion having a shape extending along the periphery of the first pad 12b-1 in plan view. In substantially the same manner as the first wiring 12g-1, the second wiring 12g-2 includes a portion having a shape extending along the periphery of the second pad 12b-2 in plan view. With this configuration, each of these portions is used as the variable resistive member, so that it is possible to place the variable resistive member close to the first semiconductor switching element 20-1 or the second semiconductor switching element 20-2, while the variable resistive member has a desired length. As a result, it is possible to improve the responsiveness of the increase in resistance value of the first wiring 12g-1 to the temperature increase of the first semiconductor switching element 20-1, and improve the responsiveness of the increase in resistance value of the second wiring 12g-2 to the temperature increase of the second semiconductor switching element 20-2.

In the example illustrated in FIG. 7, a portion of the first wiring 12g-1 and a portion of the second wiring 12g-2 in the length direction are constituted of the variable resistive member. A portion of the first wiring 12g-1, which constitutes the variable resistive member, has a shape extending along the periphery of the first pad 12b-1 in plan view. In substantially the same manner as the first wiring 12g-1, a portion of the second wiring 12g-2, which constitutes the variable resistive member, has a shape extending along the periphery of the second pad 12b-2 in plan view. Each of the first wiring 12g-1 and the second wiring 12g-2 may be made up of the variable resistive member in its entirety.

The first wiring 12g-1 is located remotely from the second pad 12b-2 in plan view. In substantially the same manner as the first wiring 12g-1, the second wiring 12g-2 is located remotely from the first pad 12b-1 in plan view. The first wiring 12g-1 and the second wiring 12g-2 are located in this manner, so that the first wiring 12g-1 may be less likely to be affected by the temperature of the second semiconductor switching element 20-2, and the second wiring 12g-2 may be less likely to be affected by the temperature of the first semiconductor switching element 20-1. With this configuration, an optimal current balance between the first semiconductor switching element 20-1 and the second semiconductor switching element 20-2 can be maintained.

In the present embodiment, the first wiring 12g-1 has a shape extending along two sides of the first pad 12b-1 in plan view. In substantially the same manner as the first wiring 12g-1, the second wiring 12g-2 has a shape extending along two sides of the second pad 12b-2 in plan view. In the first wiring 12g-1 and the second wiring 12g-2 having the shape as described above, it is possible to place the variable resistive member close to the first semiconductor switching element 20-1 or the second semiconductor switching element 20-2, while the first wiring 12g-1 is less likely to be affected by the temperature of the second semiconductor switching element 20-2, and the second wiring 12g-2 is less likely to be affected by the temperature of the first semiconductor switching element 20-1.

As described above, also in the Third Embodiment, each of the first connection part 14B-1 and the second connection part 14B-2 includes, as a current path, the variable resistive member, so that it is possible to improve the reliability of the semiconductor module 100B in which a plurality of semiconductor switching elements 20 are electrically connected in parallel to each other, while reducing the cost associated with manufacturing of the semiconductor module 100B.

### 4. Fourth Embodiment

The Fourth Embodiment of the present disclosure is described below. In respective modes exemplified below, elements substantially the same in actions and functions as those described in the above embodiments are denoted by reference symbols used in the explanations of the above embodiments and respective detailed explanations thereof are omitted as appropriate.

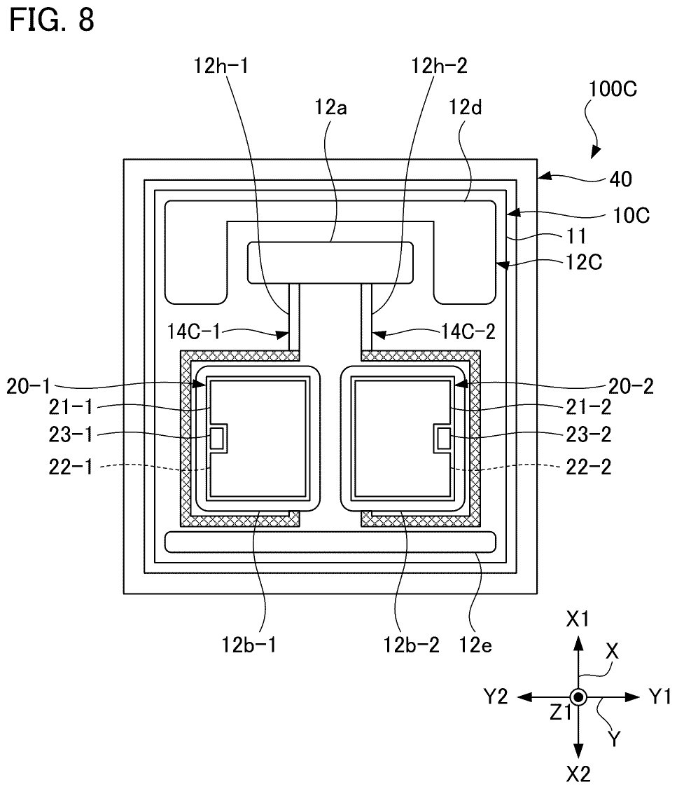

FIG. 8 is a plan view of a semiconductor module 100C according to the Fourth Embodiment. The semiconductor module 100C has substantially the same configuration as the semiconductor module 100 in the First Embodiment, except that the semiconductor module 100C includes a substrate 10C instead of the substrate 10 in the First Embodiment. In FIG. 8, for better visibility, the wires 51-1, 51-2, 52-1, and 52-2, the external input terminal 61, the external output terminal 62, and the control terminal 63 are omitted, which have been described above, and the variable resistive members are shaded.

The substrate 10C has substantially the same configuration as the substrate 10 in the First Embodiment, except that the substrate 10C includes a conductor pattern group 12C instead of the conductor pattern group 12 in the First Embodiment. The conductor pattern group 12C has substantially the same configuration as the conductor pattern group 12 in the First Embodiment, except that the conductor pattern group 12C includes a first wiring 12h-1 and a second wiring 12h-2 instead of the first wiring 12c-1 and the second wiring 12c-2 in the First Embodiment.

The first wiring 12h-1 has substantially the same configuration as the first wiring 12c-1 in the First Embodiment, except that the first wiring 12h-1 has a different shape from that of the first wiring 12c-1 in plan view. The first pad 12b-1 and the first wiring 12h-1 constitute a first connection part 14C-1, and electrically connect the input part 12a and the first input electrode 22-1. The second wiring 12h-2 has substantially the same configuration as the second wiring 12c-2 in the First Embodiment, except that the second wiring 12h-2 has a different shape from that of the second wiring 12c-2 in plan view. The second pad 12b-2 and the second wiring 12h-2 constitute a second connection part 14C-2, and electrically connect the input part 12a and the second input electrode 22-2.

Specifically, as illustrated in FIG. 8, the first wiring 12h-1 has a shape extending from the fourth side, which is in the X2 direction, of the third and fourth sides of the first pad 12b-1 extending along the Y-axis, then extending along the periphery of the first pad 12b-1, and thereafter extending toward the input part 12a in plan view. The first wiring 12h-1 extends along the fourth side of the first pad 12b-1, which is positioned in the X2 direction, the first side of the first pad 12b-1, which is positioned in the Y2 direction, and the third side of the first pad 12b-1, which is positioned in the X1 direction in plan view. In substantially the same manner as the first wiring 12h-1, the second wiring 12h-2 has a shape extending from the fourth side, which is in the X2 direction, of the third and fourth sides of the second pad 12b-2 extending along the Y-axis, then extending along the periphery of the second pad 12b-2, and thereafter extending toward the input part 12a in plan view. The second wiring 12h-2 extends along the fourth side of the second pad 12b-2, which is positioned in the X2 direction, the second side of the second pad 12b-2, which is positioned in the Y1 direction, and the third side of the second pad 12b-2, which is positioned in the X1 direction in plan view.

In this manner, the first wiring 12h-1 has a shape extending along three sides of the first pad 12b-1 in plan view. In substantially the same manner as the first wiring 12h-1, the second wiring 12h-2 has a shape extending along three sides of the second pad 12b-2 in plan view. In the first wiring 12h-1 and the second wiring 12h-2 having the shape as described above, it is possible to place the variable resistive member close to the first semiconductor switching element 20-1 or the second semiconductor switching element 20-2, while the first wiring 12h-1 is less likely to be affected by the temperature of the second semiconductor switching element 20-2, and the second wiring 12h-2 is less likely to be affected by the temperature of the first semiconductor switching element 20-1.

As described above, also in the Fourth Embodiment, each of the first connection part 14C-1 and the second connection part 14C-2 includes, as a current path, the variable resistive member, so that it is possible to improve the reliability of the semiconductor module 100C in which a plurality of semiconductor switching elements 20 are electrically connected in parallel to each other, while reducing the cost associated with manufacturing of the semiconductor module 100C.

### 5. Fifth Embodiment

The Fifth Embodiment of the present disclosure is described below. In respective modes exemplified below, elements substantially the same in actions and functions as those described in the above embodiments are denoted by reference symbols used in the explanations of the above embodiments and respective detailed explanations thereof are omitted as appropriate.

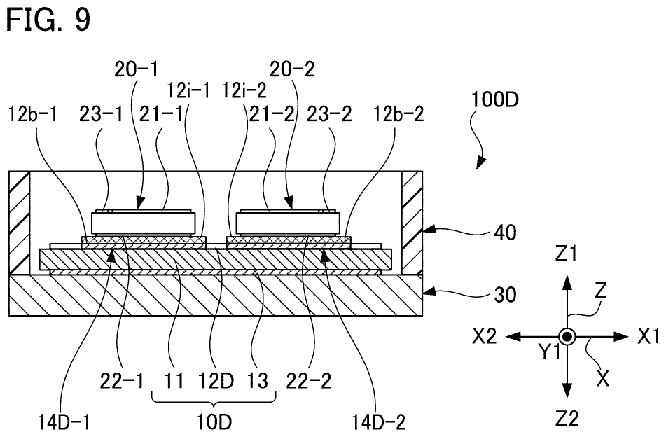

FIG. 9 is a cross-sectional view of a semiconductor module 100D according to the Fifth Embodiment. The semiconductor module 100D has substantially the same configuration as the semiconductor module 100 in the First Embodiment, except that the semiconductor module 100D includes a substrate 10D instead of the substrate 10 in the First Embodiment. In FIG. 9, for better visibility, wires 51-1, 51-2, 52-1, and 52-2, the external input terminal 61, the external output terminal 62, and the control terminal 63 are omitted, which have been described above, and the variable resistive members are shaded.

The substrate 10D has substantially the same configuration as the substrate 10 in the First Embodiment, except that the substrate 10D includes a conductor pattern group 12D instead of the conductor pattern group 12 in the First Embodiment. The conductor pattern group 12D has substantially the same configuration as the conductor pattern group 12 in the First

Embodiment, except that the conductor pattern group 12D is added with the first sheet member 12i-1 and the second sheet member 12i-2. Each of the first sheet member 12i-1 and the second sheet member 12i-2 comprises material with a positive temperature resistance coefficient higher than the temperature resistance coefficient of the material of the input part 12a.

Specifically, as illustrated in FIG. 9, the first sheet member 12i-1 is located between the first input electrode 22-1 and the first pad 12b-1, and is joined to the first input electrode 22-1 through a conductive joining material such as solder, and is joined to the first pad 12b-1 through a conductive joining material such as solder. The first sheet member 12i-1, the first pad 12b-1, and the first wiring 12c-1 constitute a first connection part 14D-1, and electrically connect the input part 12a and the first input electrode 22-1. In substantially the same manner as the first sheet member 12i-1, the second sheet member 12i-2 is located between the second input electrode 22-2 and the second pad 12b-2, and is joined to the second input electrode 22-2 through a conductive joining material such as solder, and joined to the second pad 12b-2 through a conductive joining material such as solder. The second sheet member 12i-2, the second pad 12b-2, and the second wiring 12c-2 constitute a second connection part 14D-2, and electrically connect the input part 12a and the second input electrode 22-2.

In the present embodiment, each of the first wiring 12c-1 and the second wiring 12c-2 may be made of metal such as aluminum or copper with a low temperature resistance coefficient. Each of the first sheet member 12i-1 and the second sheet member 12i-2 is not limited to the mode in which the first sheet member 12i-1 and the second sheet member 12i-2 are joined respectively to the first input electrode 22-1 and the second input electrode 22-2 through a conductive joining material such as solder, and joined respectively to the first pad 12b-1 and the second pad 12b-2 through a conductive joining material such as solder. For example, the first sheet member 12i-1 and the second sheet member 12i-2 may be formed by the vapor deposition method.

As described above, the first connection part 14D-1 includes the first sheet member 12i-1 located between the first input electrode 22-1 and the first pad 12b-1. In substantially the same manner as the first connection part 14D-1, the second connection part 14D-2 includes the second sheet member 12i-2 located between the second input electrode 22-2 and the second pad 12b-2. Each of the first sheet member 12i-1 and the second sheet member 12i-2 comprises material with a resistance value that increases due to a phase transition at a predetermined temperature or higher. This can optimally prevent the first semiconductor switching element 20-1 and the second semiconductor switching element 20-2 from being damaged by excessive increase in temperature.

Examples of the material of the first sheet member 12i-1 and the second sheet member 12i-2, that is, the material with a resistance value that increases due to a phase transition at a predetermined temperature or higher, include a conductive metal oxide such as (V_{1-X}Cr_{X})₂O₃. The conductive metal oxide undergoes a phase transition from a metallic state to a non-metallic state at a predetermined temperature in response to the temperature increase. Due to this phase transition, the resistance value of the conductive metal oxide increases sharply at the predetermined temperature or higher.

It is preferable that the predetermined temperature, that is, a temperature at which the phase transition begins when the temperature increases, fall within the range of 150° C. to 200° C. In this case, it is possible to optimally prevent the first semiconductor switching element 20-1 and the second semiconductor switching element 20-2 from being damaged by excessive increase in temperature. For example, when the conductive metal oxide described above is used, the value of X in (V_{1-X}Cr_{X})₂O₃ is preferably set to be approximately 0.005, and more specifically, is set to be equal to or greater than 0.0045 and equal to or less than 0.0055.

In the first connection part 14D-1 described above, not only does the resistance value of the first wiring 12c-1 increase due to heat from the first semiconductor switching element 20-1, but the resistance value of the first sheet member 12i-1 also increases sharply at the predetermined temperature or higher. In substantially the same manner as the first connection part 14D-1, in the second connection part 14D-2, not only the resistance value of the second wiring 12c-2 increases due to heat from the second semiconductor switching element 20-2, but the resistance value of the second sheet member 12i-2 also increases sharply at the predetermined temperature or higher.

In the manner as described above, the resistance values of the first sheet member 12i-1 and the second sheet member 12i-2 are changed, showing a different behavior from the change in resistance values of the first wiring 12c-1 and the second wiring 12c-2. Accordingly, each of the first sheet member 12i-1 and the second sheet member 12i-2 can be used to serve as a protective element of the semiconductor module 100D.

As described above, also in the Fifth Embodiment, each of the first connection part 14D-1 and the second connection part 14D-2 includes, as a current path, the variable resistive member, so that it is possible to improve the reliability of the semiconductor module 100D in which a plurality of semiconductor switching elements 20 are electrically connected in parallel to each other, while reducing the cost associated with manufacturing the semiconductor module 100D.

### 6. Sixth Embodiment

The Sixth Embodiment of the present disclosure is described below. In respective modes exemplified below, elements substantially the same in actions and functions as those described in the above embodiments are denoted by reference symbols used in the explanations of the above embodiments and respective detailed explanations thereof are omitted as appropriate.

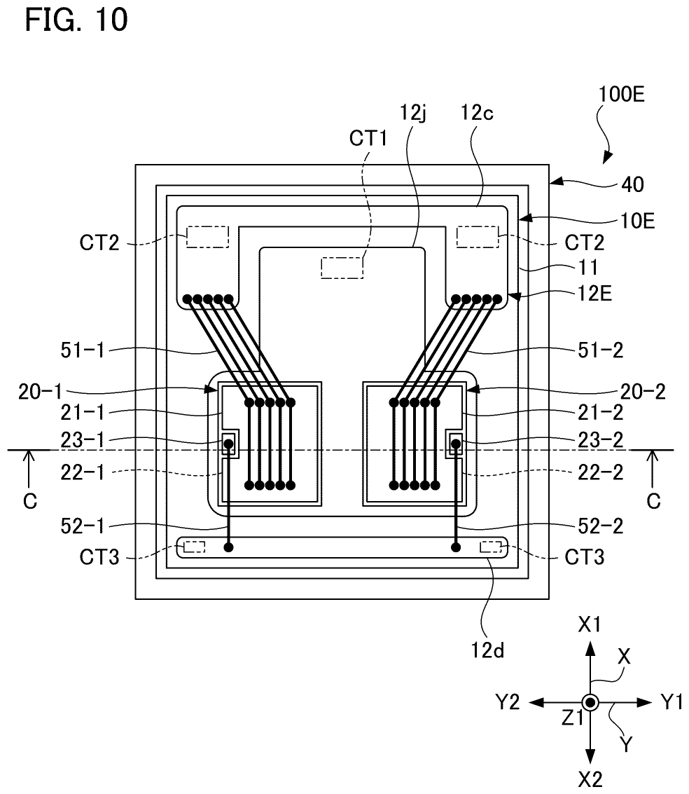

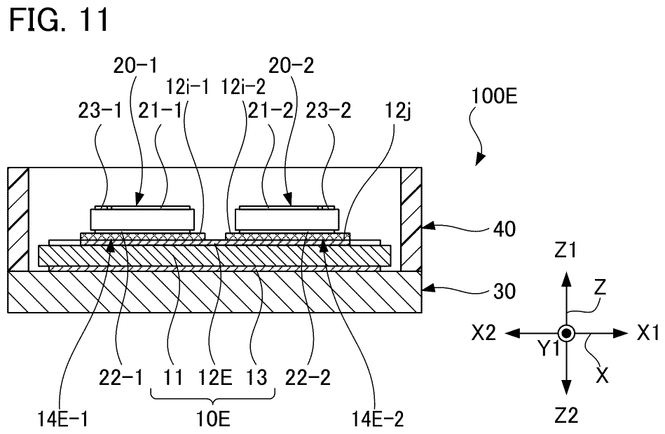

FIG. 10 is a plan view of a semiconductor module 100E according to the Sixth Embodiment. FIG. 11 is a cross-sectional view taken along a line C-C in FIG. 10. The semiconductor module 100E has substantially the same configuration as the semiconductor module 100 in the First Embodiment, except that the semiconductor module 100E includes a substrate 10E instead of the substrate 10 in the First Embodiment. In FIGS. 10 and 11, for better visibility, wires 51-1, 51-2, 52-1, and 52-2, the external input terminal 61, the external output terminal 62, and the control terminal 63 are omitted, which have been described above, and the variable resistive members are shaded.

The substrate 10E has substantially the same configuration as the substrate 10 in the First Embodiment, except that the substrate 10E includes a conductor pattern group 12E instead of the conductor pattern group 12 in the First Embodiment. The conductor pattern group 12E has substantially the same configuration as the conductor pattern group 12 in the First Embodiment, except that the conductor pattern group 12E includes an input part 12j instead of the input part 12a, the first pad 12b-1, the second pad 12b-2, the first wiring 12c-1, and the second wiring 12c-2, and is added with the first sheet member 12i-1 and the second sheet member 12i-2. The first sheet member 12i-1 and the second sheet member 12i-2 are substantially the same as the first sheet member 12i-1 and the second sheet member 12i-2 in the Fifth Embodiment described above, respectively.

The input part 12j is an input pattern made up of a conductor pattern configured to receive an input of current from the external input terminal 61. The input part 12j comprises metal material with high thermal conductivity such as copper or aluminum. Joined to the input part 12j are not only the external input terminal 61 in the region CT1 illustrated by the dash-double-dot line in FIG. 10, but also joined are the first input electrode 22-1 and the second input electrode 22-2 are joined to the input part 12j in the region CT1 illustrated by the dash-double-dot line in FIG. 10 through a conductive joining material such as solder, as illustrated in FIG. 11. As described above, the substrate 10E includes an input pattern constituting the input part 12j. The shape of the input part 12j is not limited to the example illustrated in FIG. 10, and the input part 12j may have any shape.

Specifically, as illustrated in FIG. 11, the first sheet member 12i-1 is located between the first input electrode 22-1 and the input part 12j, and is joined to the first input electrode 22-1 through a conductive joining material such as solder, and joined to the input part 12j through a conductive joining material such as solder. The first sheet member 12i-1 constitutes a first connection part 14E-1, and electrically connects the input part 12j and the first input electrode 22-1. In substantially the same manner as the first sheet member 12i-1, the second sheet member 12i-2 is located between the second input electrode 22-2 and the input part 12j, and is joined to the second input electrode 22-2 through a conductive joining material such as solder, and is joined to the input part 12j through a conductive joining material such as solder. The second sheet member 12i-2 constitutes a second connection part 14E-2, and electrically connects the input part 12j and the second input electrode 22-2. Each of the first sheet member 12i-1 and the second sheet member 12i-2 may be formed on the input part 12j by the vapor deposition method.

As described above, the first connection part 14E-1 includes the first sheet member 12i-1 located between the first input electrode 22-1 and the input part 12j. In substantially the same manner as the first connection part 14E-1, the second connection part 14E-2 includes the second sheet member 12i-2 located between the second input electrode 22-2 and the input part 12j. In substantially the same manner as in the Fifth Embodiment described above, each of the first sheet member 12i-1 and the second sheet member 12i-2 is the variable resistive member and is made of material with a resistance value that increases due to a phase transition at a predetermined temperature or higher. This can optimally prevent the first semiconductor switching element 20-1 and the second semiconductor switching element 20-2 from being damaged by an excessive increase in temperature.

As described above, also in the Sixth Embodiment, each of the first connection part 14E-1 and the second connection part 14E-2 includes, as a current path, the variable resistive member, so that it is possible to improve the reliability of the semiconductor module 100E in which a plurality of semiconductor switching elements 20 are electrically connected in parallel to each other, while reducing the cost associated with manufacturing the semiconductor module 100E.

### 7. Modifications

The present disclosure is not limited to the each of the embodiments described above and various modifications described below can be made.

The respective embodiments and the respective modifications may be appropriately combined with each other.

### 7-1. First Modification

In the embodiments described above, the semiconductor module includes two semiconductor switching elements. However, the number of semiconductor switching elements is not limited to this mode, and may be three or more. In this case, the configuration of any one of the three or more semiconductor switching elements corresponds to the configuration of “the first semiconductor switching element,” whereas the configuration of any other one of the three or more semiconductor switching elements corresponds to the configuration “the second semiconductor switching element”.

### 7-2. Second Modification

In the embodiments described above, the first semiconductor switching element and the second semiconductor switching element are installed on a common substrate. However, installation of the first semiconductor switching element and the second semiconductor switching element is not limited thereto, and the first semiconductor switching element and the second semiconductor switching element may be installed on separate substrates.

### 8. Appendix

For example, the following aspects are derivable from the embodiments or the modifications described above.

A semiconductor module according to a first aspect, which is a preferred example of the present disclosure, includes a first semiconductor switching element including a first input electrode and a first output electrode, a second semiconductor switching element including a second input electrode and a second output electrode, an input part configured to receive an input of current, a first connection part configured to electrically connect the first input electrode and the input part, a second connection part configured to electrically connect the second input electrode and the input part, and an output part electrically connected to the first output electrode and the second output electrode, in which each of the first connection part and the second connection part includes, as a current path, a variable resistive member comprising material with a positive temperature resistance coefficient higher than a temperature resistance coefficient of material of the input part.

In the first aspect described above, both the first input electrode and the second input electrode are electrically connected to the input part, while both the first output electrode and the second output electrode are electrically connected to the output part. With this configuration, the first semiconductor switching element and the second semiconductor switching element are electrically connected in parallel to each other.

The first input electrode is electrically connected to the input part through the first connection part, while the second input electrode is electrically connected to the input part through the second connection part. In addition, each of the first connection part and the second connection part includes, as a current path, a variable resistive member comprising material with a positive temperature resistance coefficient higher than the temperature resistance coefficient of material of the input part. With this configuration, a resistance value of the first connection part increases as a temperature of the first semiconductor switching element increases. Accordingly, a current to be input to the first semiconductor switching element decreases in response to the increase in temperature of the first semiconductor switching element. In substantially the same manner as the first connection part, a resistance value of the second connection part increases as a temperature of the second semiconductor switching element increases. Accordingly, a current to be input to the second semiconductor switching element decreases in response to the increase in temperature of the second semiconductor switching element.

In the configuration as described above in which the first semiconductor switching element and the second semiconductor switching element are electrically connected in parallel to each other, it is possible to prevent a current from concentrating at only one of the first semiconductor switching element and the second semiconductor switching element. As a result, it is possible to prevent a temperature increase in, and degradation of, one of the first semiconductor switching element and the second semiconductor switching element due to a current imbalance. Even when there are manufacturing variations between, or aging degradation occurs in, the first semiconductor switching element and the second semiconductor switching element, it is still possible to reduce degradation in characteristics of the semiconductor module by preventing a current from concentrating at only one of the first semiconductor switching element and the second semiconductor switching element.

The variable resistive member can be provided on the substrate configured to support the first semiconductor switching element and the second semiconductor switching element. With this configuration, the manufacturing process of the semiconductor module is further simplified, so that the cost associated with manufacturing the semiconductor module can be reduced compared to a mode in which the variable resistive member is provided on an output electrode of a semiconductor switching element as disclosed in Japanese Patent Application Laid-Open Publication No. 2000-311983.

The wording “includes, as a current path,” is defined as constituting a path through which a current mainly flows. For example, in a configuration in which a low-conductivity layer plated with nickel or the like is layered on top of a high-conductivity wiring of copper or the like, a current flows mainly through the high-conductivity wiring. Accordingly, the low-conductivity layer does not meet the definition of “includes, as a current path”.

In a second aspect which is a preferred example of the first aspect, the semiconductor module further includes a substrate configured to support the first semiconductor switching element and the second semiconductor switching element, in which each of the first connection part and the second connection part comprises a conductor pattern provided on the substrate. In the second aspect described above, it is possible to constitute the variable resistive member by using the conductor pattern on the substrate. Compared to a mode in which the variable resistive member is a bonding wire, the variable resistive member of desired characteristics can be obtained more easily.

In a third aspect which is a preferred example of the second aspect, the first connection part includes a first pad to be electrically connected to the first input electrode, and a first wiring configured to electrically connect the input part and the first pad, the second connection part includes a second pad to be electrically connected to the second input electrode, and a second wiring configured to electrically connect the input part and the second pad, and each of the first wiring and the second wiring includes the variable resistive member. In the third aspect described above, the variable resistive member of desired characteristics can be easily obtained by appropriately changing the length, shape, or other factor of the first wiring and the second wiring.

In a fourth aspect which is a preferred example of the third aspect, the variable resistive member comprises nickel or nickel alloy. In the fourth aspect described above, using this material results in a sufficiently significant change in the resistance value of the variable resistive member due to a temperature change.

In a fifth aspect which is a preferred example of the third aspect or the fourth aspect, where a cross-sectional area of the variable resistive member is represented as S [mm²] and a length of the variable resistive member is represented as L [mm], an inequality 10≤L/S≤25 is satisfied. In the fifth aspect described above, an optimal current balance between the first semiconductor switching element and the second semiconductor switching element can be maintained.

In a sixth aspect which is a preferred example of any one of the third aspect to the fifth aspect, each of the first wiring and the second wiring includes a serpentine-shaped portion in plan view. In the sixth aspect described above, such portion is used as the variable resistive member, so that it is possible to place the variable resistive member close to the first semiconductor switching element or the second semiconductor switching element, while the variable resistive member has a desired length.

In a seventh aspect which is a preferred example of any one of the third aspect to the fifth aspect, the first wiring includes a portion having a shape extending along a periphery of the first pad in plan view, and the second wiring includes a portion having a shape extending along a periphery of the second pad in plan view. In the seventh aspect described above, such portion is used as the variable resistive member, so that it is possible to place the variable resistive member close to the first semiconductor switching element or the second semiconductor switching element, while the variable resistive member has a desired length.

In an eighth aspect which is a preferred example of the seventh aspect, the first wiring is located remote from the second pad in plan view, and the second wiring is located remote from the first pad in plan view. In the eighth aspect described above, the first wiring can be less likely to be affected by the temperature of the second semiconductor switching element, and the second wiring can be less likely to be affected by the temperature of the first semiconductor switching element. With this configuration, an optimal current balance between the first semiconductor switching element and the second semiconductor switching element can be maintained.

In a ninth aspect which is a preferred example of the eighth aspect, each of the first pad and the second pad has a rectangular shape in plan view, the first wiring has a shape extending along two sides or three sides of the first pad in plan view, and the second wiring has a shape extending along two sides or three sides of the second pad in plan view. In the ninth aspect described above, it is possible to place the variable resistive member close to the first semiconductor switching element or the second semiconductor switching element, while the first wiring is less likely to be affected by the temperature of the second semiconductor switching element, and the second wiring is less likely to be affected by the temperature of the first semiconductor switching element.

In a tenth aspect which is a preferred example of any one of the third aspect to the ninth aspect, the first connection part includes a first sheet member located between the first input electrode and the first pad, the second connection part includes a second sheet member located between the second input electrode and the second pad, and each of the first sheet member and the second sheet member comprises material with a resistance value that increases due to a phase transition at a predetermined temperature or higher. In the tenth aspect described above, it is possible to optimally prevent the first semiconductor switching element and the second semiconductor switching element from being damaged by an excessive increase in temperature.

In an eleventh aspect which is a preferred example of the second aspect, the substrate includes an input pattern constituting the input part, the first connection part includes a first sheet member located between the first input electrode and the input pattern, the second connection part includes a second sheet member located between the second input electrode and the input pattern, and each of the first sheet member and the second sheet member is the variable resistive member, and the material of the variable resistive member further has a resistance value that increases due to a phase transition at a predetermined temperature or higher. In the eleventh aspect described above, it is possible to optimally prevent the first semiconductor switching element and the second semiconductor switching element from being damaged by an excessive increase in temperature.

### DESCRIPTION OF REFERENCE SYMBOLS

10 . . . substrate, 10A . . . substrate, 10B . . . substrate, 10C . . . substrate, 10D . . . substrate, 10E . . . substrate, 11 . . . insulating substrate, 12 . . . conductor pattern group, 12A . . . conductor pattern group, 12B . . . conductor pattern group, 12C . . . conductor pattern group, 12D . . . conductor pattern group, 12E . . . conductor pattern group, 12a . . . input part, 12b-1 . . . first pad, 12b-2 . . . second pad, 12c-1 . . . first wiring, 12c-2 . . . second wiring, 12d . . . output part, 12e . . . control pattern, 12f-1 . . . first wiring, 12f-2 . . . second wiring, 12g-1 . . . first wiring, 12g-2 . . . second wiring, 12h-1 . . . first wiring, 12h-2 . . . second wiring, 12i-1 . . . first sheet member, 12i-2 . . . second sheet member, 12j . . . input part, 13 . . . metal layer, 14-1 . . . first connection part, 14-2 . . . second connection part, 14A-1 . . . first connection part, 14A-2 . . . second connection part, 14B-1 . . . first connection part, 14B-2 . . . second connection part, 14C-1 . . . first connection part, 14C-2 . . . second connection part, 14D-1 . . . first connection part, 14D-2 . . . second connection part, 14E-1 . . . first connection part, 14E-2 . . . second connection part, 20-1 . . . first semiconductor switching element, 20-2 . . . second semiconductor switching element, 21-1 . . . first output electrode, 21-2 . . . second output electrode, 22-1 . . . first input electrode, 22-2 . . . second input electrode, 23-1 . . . control electrode, 23-2 . . . control electrode, 30 . . . base, 40 . . . casing, 51-1 . . . wire, 51-2 . . . wire, 52-1 . . . wire, 52-2 . . . wire, 61 . . . external input terminal, 62 . . . external output terminal, 63 . . . control terminal, 100 . . . semiconductor module, 100A . . . semiconductor module, 100B . . . semiconductor module, 100C . . . semiconductor module, 100D . . . semiconductor module, 100E . . . semiconductor module, CT1 . . . region, CT2 . . . region, CT3 . . . region, R-1 . . . internal resistance, R-2 . . . internal resistance.

What is claimed is:

1. A semiconductor module comprising:
a first semiconductor switching element including a first input electrode and a first output electrode;
a second semiconductor switching element including a second input electrode and a second output electrode;
an input part configured to receive an input of current;
a first connection part configured to electrically connect the first input electrode and the input part;
a second connection part configured to electrically connect the second input electrode and the input part; and
an output part electrically connected to the first output electrode and the second output electrode, wherein
each of the first connection part and the second connection part includes, as a current path, a variable resistive member comprising material with a positive temperature resistance coefficient higher than a temperature resistance coefficient of material of the input part.

2. The semiconductor module according to claim 1, further comprising a substrate configured to support the first semiconductor switching element and the second semiconductor switching element, wherein
each of the first connection part and the second connection part comprises a conductor pattern provided on the substrate.

3. The semiconductor module according to claim 2, wherein
the first connection part includes:
a first pad electrically connected to the first input electrode, and
a first wiring configured to electrically connect the input part and the first pad,
the second connection part includes:
a second pad electrically connected to the second input electrode, and
a second wiring configured to electrically connect the input part and the second pad, and
each of the first wiring and the second wiring includes the variable resistive member, which comprises material with a positive temperature resistance coefficient higher than the temperature resistance coefficient of the material of the input part.

4. The semiconductor module according to claim 3, wherein the variable resistive member comprises nickel or nickel alloy.

5. The semiconductor module according to claim 3, wherein where a cross-sectional area of the variable resistive member is represented as S [mm²] and a length of the variable resistive member is represented as L [mm], a relation 10≤L/S≤25 is satisfied.

6. The semiconductor module according to claim 3, wherein each of the first wiring and the second wiring includes a serpentine-shaped portion in plan view.

7. The semiconductor module according to claim 3, wherein
the first wiring includes a portion having a shape extending along a periphery of the first pad in plan view, and
the second wiring includes a portion having a shape extending along a periphery of the second pad in plan view.

8. The semiconductor module according to claim 7, wherein
the first wiring is located remote from the second pad in plan view, and
the second wiring is located remote from the first pad in plan view.

9. The semiconductor module according to claim 8, wherein
each of the first pad and the second pad has a rectangular shape in plan view,
the first wiring has a shape extending along two sides or three sides of the first pad in plan view, and
the second wiring has a shape extending along two sides or three sides of the second pad in plan view.

10. The semiconductor module according to claim 3, wherein
the first connection part includes a first sheet member located between the first input electrode and the first pad,
the second connection part includes a second sheet member located between the second input electrode and the second pad, and
each of the first sheet member and the second sheet member comprises material with a resistance value that increases due to a phase transition at a predetermined temperature or higher.

11. The semiconductor module according to claim 2, wherein
the substrate includes an input pattern constituting the input part,
the first connection part includes a first sheet member located between the first input electrode and the input pattern,
the second connection part includes a second sheet member located between the second input electrode and the input pattern, and
each of the first sheet member and the second sheet member is the variable resistive member, the material of which has a positive temperature resistance coefficient higher than the temperature resistance coefficient of the material of the input part, wherein a resistance value of the material of the variable resistive member increases due to a phase transition at a predetermined temperature or higher.
